(19) United States
(12) Patent Application Publication
(10) Pub. No.: US 2024/0310447 A1
(43) Pub. Date: Sep. 19, 2024

(54) METHOD FOR ESTIMATING THE STATE OF CHARGE OF AN ELECTROCHEMICAL ELEMENT AND ASSOCIATED DEVICES

(71) Applicant: SAFT, LEVALLOIS PERRET (FR)

(72) Inventors: Daniel MONIER-REYES, AVENSAN (FR); Sébastien BENJAMIN, LEOGNAN (FR)

(73) Assignee: SAFT, LEVALLOIS PERRET (FR)

(21) Appl. No.: 18/576,962

(22) PCT Filed: Jul. 6, 2022
(86) PCT No.: PCT/EP2022/068713

§ 371 Date: Jan. 5, 2024

(30) Foreign Application Priority Data
Jul. 6, 2021 (FR) FR2107294

(51) Int. Cl. G01R 31/367; G01R 31/374; G01R 31/3842; H01M 10/42; H01M 10/48

(52) U.S. Cl. CPC G01R 31/367; G01R 31/374; G01R 31/3842; H01M 10/425; H01M 10/48; H01M 10/486; H01M 2010/4271

(57) ABSTRACT

The invention relates to a method for detecting the state of charge of an electrochemical element, the method comprising the steps of:
obtaining the voltage, current, temperature and capacity of the electrochemical element,
computing the state of charge of the electrochemical element using two techniques:
a first technique giving the value of the first model applied to the aforementioned values and corrected by the correction function, the first model being a neural network, the correction function giving for each value of the state of charge the statistical estimation error of the first model; and
a coulometric second technique,
determining the most reliable technique depending on a reliability criterion of the corrected first model, and
the value computed using the determined technique being the estimated value of the state of charge.

### CROSS REFERENCE TO RELATED APPLICATIONS

The present application is a U.S. National Phase Application under 35 U.S.C. § 371 of International Patent Application No. PCT/EP2022/068713 filed Jul. 6, 2022, which claims priority of French Patent Application No. 21 07294 filed Jul. 6, 2021. The entire contents of which are hereby incorporated by reference.

### FIELD OF THE INVENTION

The present invention relates to a method for estimating the state of charge of at least one electrochemical element of a battery. The present invention further relates to an associated calculator, an associated management system and an associated battery.

### BACKGROUND

Typically, a battery comprises one or a plurality of current accumulators also called electrochemical generators, cells or elements. An accumulator is a device for producing electricity wherein chemical energy is converted into electrical energy. The chemical energy comes from electrochemically active compounds deposited on at least one face of electrodes arranged in the accumulator. Electrical energy is produced by electrochemical reactions during a discharge of the accumulator. The electrodes are arranged in a container and are electrically connected to current output terminals which provide electrical continuity between the electrodes and an electrical consumer with which the accumulator is associated.

In order to increase the electrical power delivered, it is possible to combine a plurality of accumulators, sealed from one another, to form a battery. Thereby, a battery can be divided into modules, each module being composed of one or a plurality of accumulators connected together in series and/or in parallel. Thereby, a battery can e.g. comprise one or a plurality of parallel branches of accumulators connected in series and/or one or a plurality of parallel branches of modules connected in series.

A charger circuit is generally provided to which the battery can be connected in order to recharge the accumulators.

Moreover, an electronic management system comprising measurement sensors and an electronic control circuit, variably advanced depending on the applications, can be associated with the battery. Such a system can be used in particular for organizing and controlling the charging and discharging of the battery, in order to balance the charging and discharging of the different accumulators of the battery with respect to one another.

The state of charge is useful information for the electronic battery management system, in order to optimize the use and life thereof. The state of charge is often referred to by the abbreviation SOC thereof.

To obtain the state of charge (SOC), it is known how to use two computation techniques using continuous measurements of the change of voltage, current and temperature.

The first technique can be described as “coulometric” insofar as same uses the fact that the state of charge (SOC) depends on the charge (Ampere-hour count) and of the capacitance C of the battery.

Indeed, the following formulas follow therefrom:

$$SOC = {SOC}_{0} + \frac{{\int }_{0}^{t} I \times dt}{C}$$

Where: SOC₀ Is the initial value of the state of charge (SOC) at the instant t=0.

However, the first technique is very sensitive to the measurement error on the current and to the estimation of capacitance. As a result, the use of such technique alone leads to the accumulation of the measurement error on the current, which leads to an erroneous estimation of the state of charge.

The second technique is based on open circuit voltage (OCV) measurements and uses a pre-established lookup table for obtaining the state of charge (SOC) as a function of the open circuit voltage. The open circuit voltage is often referred to by the abbreviation OCV thereof.

Since the function that links the open circuit voltage (OCV) to the state of charge (SOC) is a function of the voltage from which the product of resistance and current is subtracted, the second technique is a technique sensitive to the estimation of resistance. Also, the second technique should be used under conditions that minimize the error on the resistance, i.e. quiescent conditions or low current conditions.

It is known how to use the two aforementioned techniques by using the first technique as the usual technique and by regularly recalibrating the state of charge (SOC) using the second technique.

However, in certain electrochemical elements, because the variation of the open circuit voltage as a function of the state of charge (SOC) has a plateau, the correspondence between the open circuit voltage (OCV) and the state of charge (SOC) may be false.

Thereby, it is known to perform a resetting by carrying out a re-calibration with a state of charge (SOC) higher than the maximum state of charge (SOC) corresponding to the end of the plateau.

Such a technique then generally imposes the interruption of the mission of the electrochemical element, so as to carry out the recharge. In particular, such is the case for frequency regulation missions that involve cycles on the plateau. Such interruptions could be incompatible with the mission.

There is thus a need for a method of estimating the state of charge (SOC) of an electrochemical element, that is more precise and can be achieved in normal operation of the electrochemical element.

### SUMMARY

To this end, the description describes a method for estimating the state of charge of at least one electrochemical element of a battery, the method being implemented by a calculator, the calculator storing a first model giving, from a value of voltage, a value of current, a value of temperature and a value of capacitance of the at least one electrochemical element, the value of the state of charge of the at least one electrochemical element, the first model being a trained neural network, the calculator storing a correction function giving for each value of the state of charge the statistical error of estimation by the first model, the method comprising, for a plurality of instants, the steps of:
obtaining values of the voltage, the current, the temperature and the capacitance of at least one electrochemical element,
computation of the value of the state of charge of at least one electrochemical element according to at least one technique, the technique being a first technique or a second technique,
the first technique including the following operations:
   application of the first model to the value of the voltage, the current, the temperature and the capacitance of the at least one electrochemical element at the same instant, so as to obtain an estimated value of the state of charge, and
   application of the correction function to the estimated value of the state of charge, for obtaining a first computed value of the state of charge,
the second technique including the following operations:
   computation of the value of the amount of charge accumulated by using the obtained values of current,
   deduction of a second computed value of the state of charge by computing the ratio of the value of the accumulated charge quantity and the capacitance of the at least one electrochemical element,
determination of the most reliable technique among the first technique and the second technique according to a reliability criterion depending on the value of the statistical error of estimation of the model corresponding to the first model corrected by the correction function for the first computed value of the state of charge,
computation of the computed value of the state of charge according to the technique determined as being reliable if the value has not been computed previously, and
selection of the computed value of the state of charge according to the technique determined as the estimated value of the state of charge.

According to particular embodiments, the estimation method has one or a plurality of the following features, taken individually or according to all technically possible combinations:
a step of correcting the computed accumulated charge quantity used by the second technique so that the computation of the second technique leads to obtaining the first computed value of the state of charge (SOC) when the first technique is determined as being reliable.
a step of correcting the value of the current obtained by subtracting the measurement bias on the current, in order to obtain a corrected value of the current, the computation steps being applied to the corrected value of the current.
when the first technique is determined as being reliable at an instant after a time interval during which the second technique has been determined as being reliable at each instant in the time interval, a step of determining the measurement bias on the current by using the difference of state of charge between the two techniques since the beginning of the time interval.
the neural network of the first model is a multilayer perceptron.
the neural network of the first model includes a number of neurons less than or equal to 100.
at least one electrochemical element has a state of charge—open circuit voltage curve with a flat portion, a flat portion being a portion wherein the variation of the open circuit voltage is less than 30 mV for a variation of at least 10% of the state of charge.
at least one electrochemical element 12 comprises an active cathode material chosen from the following groups or mixtures thereof:
   i) a compound with the formula LiₓFe_{1-y}M_{y}PO₄ LFMP where M is selected from the group consisting of B, Mg, Al, Si, Ca, Ti, V, Cr, Mn, Co, Ni, Cu, Zn, Y, Zr, Nb, and Mo; and 0.8≤x≤1.2; 0≤y≤0.6;
   ii) a compound with the formula LiₓMn_{1-y-z}M′_{y}M″_{z}PO₄ LMP, where M′ and M″ are different from each other and are chosen from the group consisting of B, Mg, Al, Si, Ca, Ti, V, Cr, Fe, Co, Ni, Cu, Zn, Y, Zr, Nb, and Mo, with 0.8≤x≤1.2; 0≤y≤0.6; 0≤z≤0.2;
   iii) a compound with the formula LiₓMn_{2-y-z}Ni_{y}M_{z}O_{4-d-c}F_{c} LMNO, where M represents one or a plurality of elements chosen from the group consisting of B, Mg, Al, Si, Ca, Ti, V, Cr, Fe, Co, Ni, Cu, Zn, Y, Zr, Nb, and Mo; and 1≤x≤1.4; 0≤y≤0.6; 0≤z≤0.2; 0≤d≤1; 0≤c≤1,
   iv) a compound with the formula LiₓMn_{2-y-z}M′_{y}M″_{z}O₄ (LMO), where M′ and M″ are chosen from the group consisting of B, Mg, Al, Si, Ca, Ti, V, Cr, Fe, Co, Ni, Cu, Zn, Y, Zr, Nb, and Mo; M′ and M″ being different from each other, and 1≤x≤1.4; 0≤y≤0.6; 0≤z≤0.2; and
v) a compound with the formula LiVPO₄F (LVPF).

The description also proposes a calculator suitable for estimating the state of charge of at least one electrochemical element of a battery, the calculator storing a first model giving, from a value of voltage, a value of current, a value of temperature and a value of capacitance of the at least one electrochemical element, the value of the state of charge of the at least one electrochemical element, the first model being a trained neural network, the calculator storing a correction function giving, for each value of the state of charge, the statistical error of estimation by the first model, the calculator being, for a plurality of instants, suitable for:
obtaining values of the voltage, the current, the temperature and the capacitance of at least one electrochemical element,
computing the value of the state of charge of at least one electrochemical element according to at least one technique, the technique being a first technique or a second technique,
the first technique including the following operations:
   application of the first model to the value of the voltage, the current, the temperature and the capacitance of the at least one electrochemical element at the same instant, so as to obtain an estimated value of the state of charge, and
   application of the correction function to the estimated value of the state of charge, for obtaining a first computed value of the state of charge,
the second technique involves the following operations:
   computation of the value of the amount of charge accumulated by using the obtained values of current,
   deduction of a second computed value of the state of charge by computing the ratio of the value of the accumulated charge quantity and the capacitance of the at least one electrochemical element,
determination of the most reliable technique among the first technique and the second technique according to a reliability criterion depending on the value of the statistical error of estimation of the model corresponding to the first model corrected by the correction function for the first computed value of the state of charge,
computation of the computed value of the state of charge according to the technique determined as being reliable if the value has not been computed previously, and
selection of the computed value of the state of charge according to the determined technique as the estimated value of the state of charge.

According to a particular embodiment, the calculator is suitable for correcting the computed accumulated charge quantity used by the second technique so that the computation of the second technique leads to obtaining the first computed value of the state of charge when the first technique is determined as being reliable.

The description further describes a management system for at least one electrochemical element of a battery, the at least one electrochemical element having terminals, the management system comprising a voltage sensor apt to measure the voltage at the terminals of the at least one electrochemical element, a sensor for the current at the terminals of the said at least one electrochemical element, a temperature sensor of said at least one electrochemical element, and a calculator as described hereinabove.

The description further proposes a battery comprising at least one electrochemical element, and a management system as described hereinabove.

### BRIEF DESCRIPTION OF THE DRAWINGS

The features and advantages of the invention will appear upon reading the following description, given only as an example, but not limited to, and making reference to the enclosed drawings, wherein:

FIG. 1 is a schematic representation of an example of battery including an electrochemical element,

FIG. 2 is a graph illustrating an example of the open circuit voltage—state of charge characteristic curve of the electrochemical element shown in FIG. 1,

FIG. 3 is a flowchart of an example of implementation of a method for estimating the state of charge of the electrochemical element, and

FIGS. 4 to 8 illustrating experimental curves that can be obtained after the implementation of certain steps of the estimation method described in FIG. 3.

### DETAILED DESCRIPTION

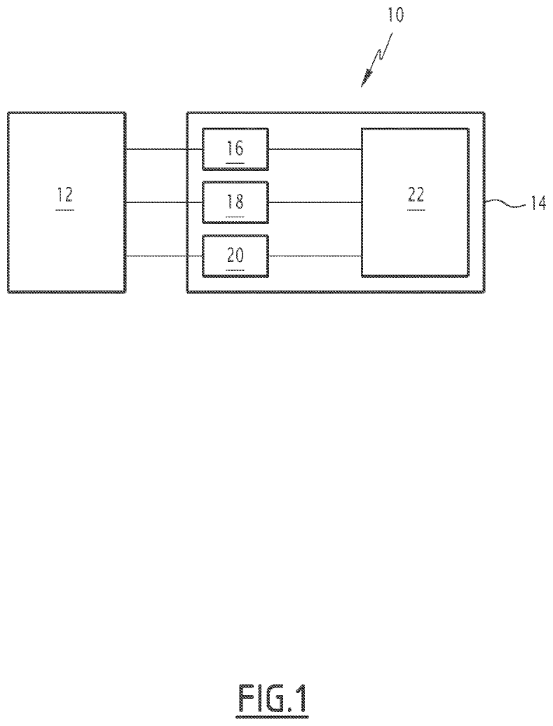

A battery 10 is shown in FIG. 1.

In a manner known per se, a battery is generally an arrangement of a plurality of electrochemical elements, but, to simplify the discussion, a case with a single electrochemical element is described hereinafter, knowing that the transposition to other arrangements is immediate.

The battery 10 includes an electrochemical element 12 and a management system 14 for the electrochemical element 12.

As explained hereinabove, an electrochemical element 12 is a device for producing electricity wherein chemical energy is converted into electrical energy.

Therefore, the electrochemical element 12 delivers a current and a voltage between two terminals.

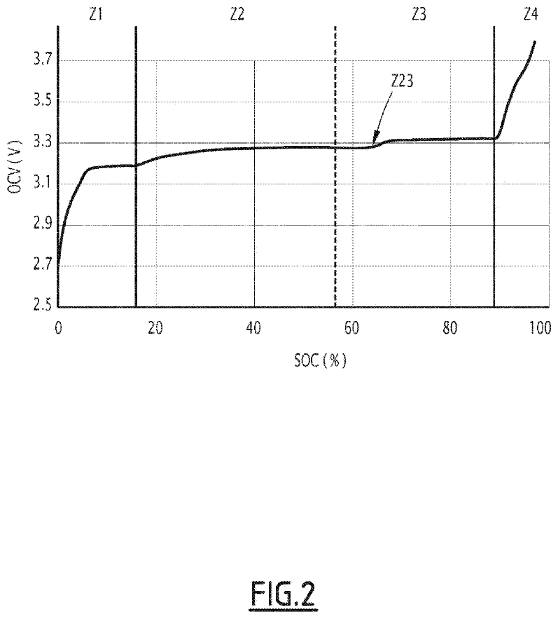

The electrochemical element 12 has an open circuit voltage—state of charge SOC characteristic curve as shown in FIG. 2. Hereinafter, the characteristic curve is referred to as the OCV/SOC characteristic.

In FIG. 2, the state of charge (SOC) is expressed as a percentage of a maximum state of charge.

The OCV-SOC characteristic has four zones, a first zone Z1, a second zone Z2, a third zone Z3 and a fourth zone Z4.

The first zone Z1 corresponds to the start of charging and the fourth zone Z4 corresponds to the end of charging.

For the two intermediate zones, insofar as the second zone Z2 and the third zone Z3 correspond to a flat portion, the term flat portion (Z23) will be used hereinafter.

The flat portion Z23 is a portion wherein the variation of the open circuit voltage OCV is less than 30 mV for a variation of at least 10% of the state of charge (SOC).

Such a type of OCV-SOC characteristic is found in particular when the electrochemical element 12 is a comprising a cathode active material chosen in the following groups or mixtures thereof:
a compound with the formula LiₓFe_{1-y}M_{y}PO₄ (LFMP) where M is selected from the group consisting of B, Mg, Al, Si, Ca, Ti, V, Cr, Mn, Co, Ni, Cu, Zn, Y, Zr, Nb, and Mo; and 0.8≤x≤1.2; 0≤y≤0.6;
ii) a compound with the formula LiₓMn_{1-y-z}M′_{y}M″_{z}PO₄ (LMP), where M′ and M″ are different from each other and are selected from the group consisting of B, Mg, Al, Si, Ca, Ti, V, Cr, Fe, Co, Ni, Cu, Zn, Y, Zr, Nb, and Mo, with 0.8≤x≤1.2; 0≤y≤0.6; 0≤z≤0.2;
iii) a compound with the formula LiₓMn_{2-y-z}Ni_{y}M_{z}O_{4-d-c}F_{c} (LMNO), where M represents one or a plurality of elements chosen from the group consisting of B, Mg, Al, Si, Ca, Ti, V, Cr, Fe, Co, Ni, Cu, Zn, Y, Zr, Nb, and Mo; and 1≤x≤1.4; 0≤y≤0.6; 0≤z≤0.2; 0≤d≤1; 0≤c≤1,
iv) a compound with the formula LiₓMn_{2-y-z}M′_{y}M″_{z}O₄ (LMO), where M′ and M″ are chosen from the group consisting of B, Mg, Al, Si, Ca, Ti, V, Cr, Fe, Co, Ni, Cu, Zn, Y, Zr, Nb, and Mo; M′ and M″ being different from each other, and 1≤x≤1.4; 0≤y≤0.6; 0≤z≤0.2; and
v) a compound with the formula LiVPO₄F (LVPF).

The active anode material is not particularly limited. Same is a material apt to insert lithium into the structure thereof. The active anode material may be chosen from lithium compounds and carbon-containing materials such as graphite, coke, carbon black and vitreous carbon. Same can also be based on tin, silicon, compounds containing carbon and silicon, compounds containing carbon and tin or compounds containing carbon, tin and silicon. The active anode material can also be a lithiated titanium oxide such as Li₄Ti₅O₁₂ or a niobium titanium oxide such as TiNb₂O₇.

The management system 14 is a system apt to manage the electrochemical element 12.

The management system 14 includes a voltage sensor 16, a sensor for current 18, a temperature sensor 20 and a calculator 22.

The voltage sensor 16 is suitable for measuring the voltage across the terminals of the electrochemical element 12.

The sensor for current 18 is suitable for measuring the current across the electrochemical element 12.

The temperature sensor 20 is suitable for measuring the temperature across the terminals of the electrochemical element 12.

The calculator 22 is apt to implement a method for estimating the state of charge of the electrochemical element 12.

The calculator 22 is an electronic circuit designed for handling and/or transforming data represented as electronic or physical quantities in registers of the calculator and/or memories in other similar data corresponding to physical data in the register memories or other types of displays, transmission devices or storage devices.

As specific examples, the calculator 22 comprises a single-core or multi-core processor (such as a central processing unit (CPU), a graphics processing unit (GPU), a microcontroller and a digital signal processor (DSP), a programmable logic circuit (such as an application specific integrated circuit (ASIC), an in situ array of field programmable gates (FPGAs), a programmable logic device (PLD) and programmable logic arrays (PLAs), a state machine, a logic gate, and discrete hardware components.

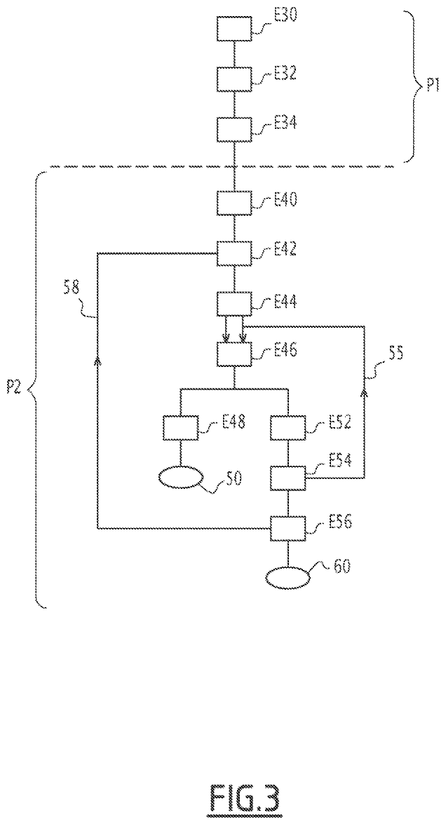

An example of implementation of the method for estimating the state of charge SOC is now described with reference to the flow chart shown in FIG. 3.

The method for estimating the state of charge (SOC) includes two phases, a learning phase P1 and an operation phase P2.

According to the example described, the learning phase P1 is implemented offline, i.e. the learning phase is not embedded.

The learning phase P1 includes a learning step E30 of a neural network, a computation step E32 and a setting-up step E34.

During the learning step E30, the neural network is trained to estimate the state of charge SOC of the electrochemical element 12 from the values of voltage of the electrochemical element 12, of current of the electrochemical element 12, of temperature of the electrochemical element 12 and of capacitance C of the electrochemical element 12.

The values of the voltage, the current and the temperature come from the voltage sensor 16, the sensor for current 18 and the temperature sensor 20, respectively.

According to the example described, such values are measured regularly.

The value of capacitance C is obtained less frequently and can be obtained by any technique, in particular by determination during a complete charge or discharge.

The neural network to train is a multilayer perceptron.

Such a network is often referred to by the abbreviation MLP.

Thereby, a neural network consists of an ordered succession of neuron layers, each of which takes the inputs thereof from the outputs of the preceding layer.

More precisely, each layer comprises neurons taking the inputs thereof from the outputs of the neurons of the preceding layer.

In the example, the layers are dense, i.e. a neuron of one layer takes the inputs of all the neurons of the preceding layer. The expression “fully connected” is sometimes used to refer to such type of layer.

Each layer is linked by a plurality of synapses. A synaptic weight is associated with each synapse. Same is most often a real number that can take positive as well as negative values.

Each neuron is apt to perform a weighted sum of the value(s) received from the neurons of the preceding layer, each value then being multiplied by the respective synaptic weight, then to apply an activation function, typically a non-linear function, to said weighted sum, and to deliver to the neurons of the next layer, the value resulting from the application of the activation function. The activation function is used for introducing a non-linearity in the processing performed by each neuron. The sigmoid function, the hyperbolic tangent function, the Heaviside function are examples of activation functions.

The neural network to train is an easy to embed neural network.

It is also suitable that the neural network has a limited number of neurons.

For example, the total number of the neural network is on the order of a hundred neurons, preferentially 100 neurons.

In the example described, the neural network comprises a plurality of layers, namely an input layer, a hidden layer and one or a plurality of output layers.

The neural network is trained using a supervised learning technique.

Thereby, it is a question of learning the free parameters of the neural network from a data set obtained by real experiments in the laboratory, typically for more than 100 different electrochemical elements 12.

During such experiments, electrochemical elements 12 undergo successive cycles and the electrical values of the electrochemical elements 12 (current, voltage, state of charge, capacitance) and the value of temperatures are read for forming the data set.

The data set is then separated into a training set and a test set, e.g. in a proportion of 80%-20%.

The training set is used so that the neural network learns the different free parameters thereof by successive iterations until satisfying a desired performance criterion. A network of trained neurons is thereby obtained.

The test set is then used for evaluating the performance of the trained neural network.

Thereby, the neural network forms, for the electrochemical element 12, a first model M1 estimating a value of the state of charge SOC from the values of voltage, current, temperature and capacitance.

The first model M1 is rather robust against even strong biases of current, due to the structure thereof based on a multilayer perceptron that has no memory effect, i.e. that uses only values of current and the preceding values for obtaining the desired estimation.

Moreover, due to small size thereof, the first model M1 is easy to embed because the memory footprint and the processor footprint of the model are reduced.

Nevertheless, as a result, such a first model M1 presents an estimation error, i.e. a difference between the estimated value and the real value, which is relatively significant under certain conditions.

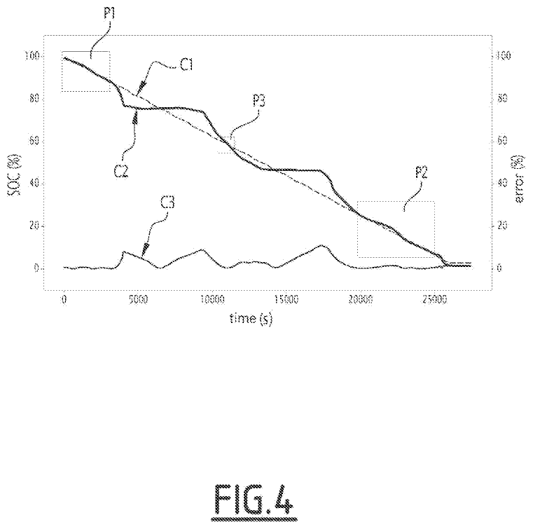

FIG. 4 graphically illustrates the performance obtained experimentally using the first model M1 in the absence of any bias of current.

In FIG. 4, the first curve C1 corresponds to the real value of the state of charge (SOC), the second curve C2 corresponds to the value estimated by the first model M1 and the third curve C3 corresponds to the estimation error.

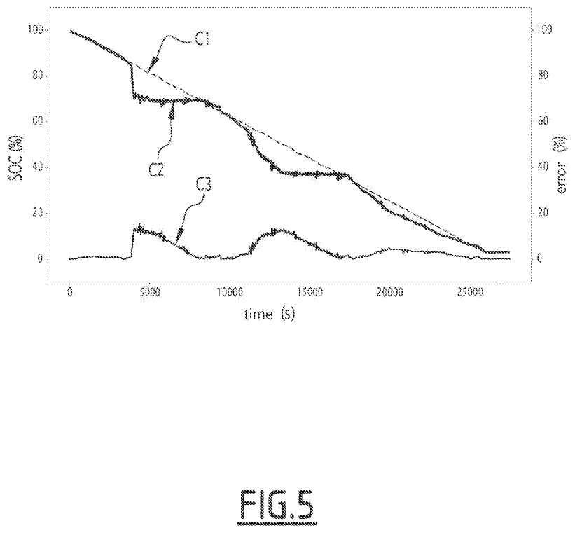

The estimation is imperfect except in the three framed portions shown in FIG. 4. Such portions correspond to the first zone Z1, to the fourth zone Z4 and to the junction between the second zone Z2 and the third zone Z3. Moreover, the robustness to biases of current can be seen by comparing FIG. 4 to FIG. 5 which corresponds to the performance of the first model M1 in the presence of a bias of current. The error observed is very little increased.

During the computation step E32, the statistical estimation error is computed in the form of a first table TAB1.

To this end, the difference between the value estimated by the first model M1 and the actual value of the state of charge (SOC) for each element of the training data set, is computed.

To limit the storage space allocated to the first table TAB1, the values of state of charge (SOC) are grouped according to a predefined range.

In the present case, the range is a value of 1%. The above means that all states of charge (SOCs) equal to each other within 1% are considered to be the same state of charge (SOC). The above means considering an accuracy on the order of 1% in measuring the state of charge (SOC).

A set of a plurality of errors is thereby obtained for each actual value of the state of charge (SOC), one error for each element of the data set having the same value of the state of charge (SOC).

The mean of the errors associated with an actual value of the state of charge (SOC) is then computed for obtaining the statistical error associated with the actual value of the state of charge (SOC). The computed mean is, according to the proposed example, an arithmetic mean.

The first table TAB1 then associates with each actual value of the state of charge (SOC) the statistical estimation error of the first model M1.

The statistical error is then the mean deviation from the estimated value.

When the statistical error is positive, it means that the estimated value is overestimated while for a negative statistical error, the estimated value is underestimated.

As a remark, it should be noted that the previous tabular formalism can be seen under the formalism of a correction function corresponding to an interpolation of the values of the table.

Such change of formalism makes it possible to obtain exactly the same results as with the results obtained with the first table TAB1, formalism which will be used hereinafter.

Such a first table TAB1 can be used for obtaining a second model M2 obtained by correcting the first model M1 with the first table TAB1.

Such a model is sometimes referred to as a self-correcting model. Such self-correction is made possible by the fact that the first table TAB1 is not very sensitive to the input data provided that the first model M1 is supplied thereto.

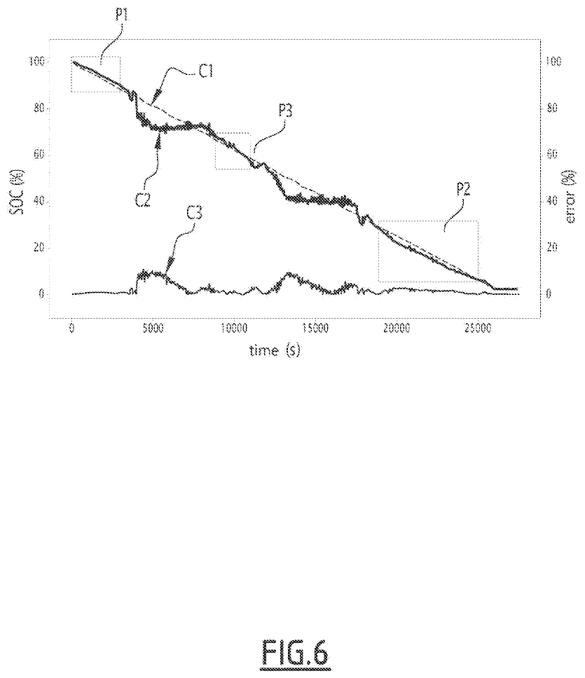

The performance obtained by such a second model M2 is shown in FIG. 6 with the same conventions as for FIG. 4.

The comparison of FIG. 6 with FIG. 4 shows that the second portion P2 and the third portion P3 are wider, which makes it possible to obtain three portions used for performing a recalibration, as will be subsequently described.

During the setting-up step E34, a second table TAB2 is established relating to the model obtained by correcting the first model M1 with the first table TAB1, i.e. the second model M2.

From the values of state of charge (SOC) obtained by the self-corrected model, it is possible to set up the second table TAB2 by indicating a “reliable” and “unreliable” indication according to a threshold for the statistical error corresponding to the second model M2.

Thereby e.g., if the statistical error of the second model M2 is greater than the threshold, the value of state of charge (SOC) is not reliable, and vice versa, if the statistical error of the second model M2 is less than or equal to the threshold, the value of state of charge (SOC) is reliable.

For example, the threshold is set according to the desired precision for the model.

The neural network and the two tables TAB1 and TAB2 are loaded into a memory of the calculator 22.

The calculator 22 is thereby ready to implement the operation phase.

Unlike the learning phase P1 which is performed only once, the operation phase P2 is implemented for a plurality of instants.

More particularly, the operation phase P2 corresponds to a real-time operation phase of the battery 10.

For example, the instants are equally distributed, e.g. spaced apart by a time interval comprised between 100 milliseconds (ms) and 2 seconds (s).

The steps of the operation phase P2 are implemented for each instant.

In the above sense, it can thus be considered that the operation phase P2 is iterative and that at each instant of implementation, an iteration takes place.

According to the example described, the operation phase P2 is implemented online, i.e. the operation phase P2 is embedded and thus implemented by the calculator 22.

Furthermore, as can be seen in FIG. 3, the operation phase P2 comprises an obtaining step E40, a correction step E42, a computation step E44, a determination step E46, a selection step E48 or E52 and, if appropriate, another correction step E54 and determination step E56.

During the obtaining step E40, the calculator 22 obtains measurements (values) of the voltage V, of the current I, of the temperature T and of the capacitance C of the electrochemical element 12.

During the correction step E42, the calculator 22 subtracts the measurement bias on current from the value of the current I obtained.

The measurement bias on current results in particular from the measurement bias intrinsic to the sensor for current 18 and on the variable accuracy thereof as a function of the amplitude of the current to be measured.

The calculator 22 thereby obtains a corrected value of current I.

When the measurement bias is not known, the bias is considered to be zero.

During the computation step E44, the calculator 22 computes the value of the state of charge (SOC) according to two distinct techniques, as illustrated schematically in FIG. 3 by two arrows towards the determination step E46.

According to a first technique, the calculator 22 applies the first model M1 to the value of voltage V obtained, the corrected value of current I, the value of temperature T and the value of capacitance C obtained during the obtaining step E40.

The above amounts to producing an inference using the neural network trained offline so as to obtain a value of state of charge (SOC) without self-correction.

The calculator 22 thereby obtains a value of the estimated state of charge (SOC).

The calculator 22 then applies the correction of the first table TAB1 to the value of the estimated state of charge (SOC).

To this end, the calculator 22 reads the value of the error corresponding to the range to which the estimated value of state of charge (SOC) belongs and subtracts the value read from the estimated value.

A corrected value of state of charge SOC is thereby obtained, which corresponds to the value of state of charge (SOC) obtained according to the first technique denoted by SOC_{TECH1}.

Due to the simultaneous use of the first model M1 and of the first table TAB1, the first technique corresponds to the use of a self-corrected neural network.

According to a second technique, the calculator 22 performs the so-called coulometric technique described hereinabove. Such a technique corresponds to a second model M2.

Such technique is based on the fact that the state of charge (SOC) of an electrochemical element 12 depends directly on the ratio between the amount of charge accumulated (or ampere-hour count with reference to the unit often used for such amount) and the capacitance of the electrochemical element 12.

Thereby, the calculator 22 then uses the value of currents and the value of capacitance according to the following formula:

$$SOC = {SOC}_{0} + \frac{{\int }_{0}^{t} I \times dt}{C}$$

More precisely, the calculator 22 holds in memory a value of the quantity of charge accumulated at the preceding iteration Ah_{preceding}, adds to said value the result of the time integration of the corrected value of the current over the interval of time elapsed since the preceding iteration. The value thereby obtained is the value of the quantity of charge accumulated at the current iteration Ah_{current}, said value being stored by the calculator 22.

The calculator 22 then performs the division by the value of the capacitance and thereby obtains a value of the state of charge (SOC) according to the second technique SOC_{TECH2}.

At the end of the computation step, the computer 22 thereby has two distinct values of the state of charge (SOC) of the electrochemical element 12, namely SOC_{TECH1} and SOC_{TECH2}.

According to the example described, during the determination step E46, the calculator 22 determines whether the value of the state of charge according to the first technique SOC_{TECH1} is a reliable value.

According to the example described, the calculator 22 uses the second table TAB2.

Thereby, the second table TAB2 serves to determine whether the value of the state of charge according to the first technique SOC_{TECH1} is within a confidence interval.

At the end of the determination step E46, the calculator 22 has determined that the value of the state of charge according to the first technique SOC_{TECH1} is either unreliable or reliable.

In the case where the value of the state of charge according to the first technique SOC_{TECH1} is unreliable, it means that the value of the state of charge according to the second technique SOC_{TECH2} is more reliable than the value of the state of charge according to the first technique SOC_{TECH1}.

The calculator 22 then considers that the value of the estimated state of charge (SOC) is equal to the value of the state of charge according to the second technique SOC_{TECH2} and selects, during the selection step E48, the value of the state of charge according to the second technique SOC_{TECH2} as the final estimated value of the state of charge (SOC), i.e. the output value of the estimation process.

The output of the final estimated value of the state of charge (SOC) is illustrated schematically in FIG. 1 by the element 50. The final estimated value is e.g. displayed on a display device.

On the other hand, in the case where the value of the state of charge according to the first technique SOC_{TECH1} is reliable, it means that the value of the state of charge according to the first technique SOC_{TECH1} is more reliable than the value of the state of charge according to the second technique SOC_{TECH2}.

The calculator 22 then considers that the value of the state of charge (SOC) measured is equal to the value of the state of charge according to the first technique SOC_{TECH1} and selects during the selection step E52, the value of the state of charge according to the first technique SOC_{TECH1} as the final estimated value of the state of charge (SOC), i.e. the output value of the estimation process.

The calculator 22 then implements the correction step E54.

The calculator 22 then calculates a value of accumulated charge quantity corresponding to the value of the state of charge according to the first technique SOC_{TECH1} by using the value of the capacitance C.

The calculator 22 then corrects the second model M2 by modifying the value of the quantity of charge accumulated at the current iteration Ah_{current} which becomes the value previously deduced by means of the first technique.

It can be interpreted that, in such case, the ampere-hour counter is reset to the value that can be deduced using the first self-corrected model.

The correction step E54 which has just been described corresponds to a recalibration step of the second model M2.

Such recalibration is schematically represented, in FIG. 3, by the arrow 55.

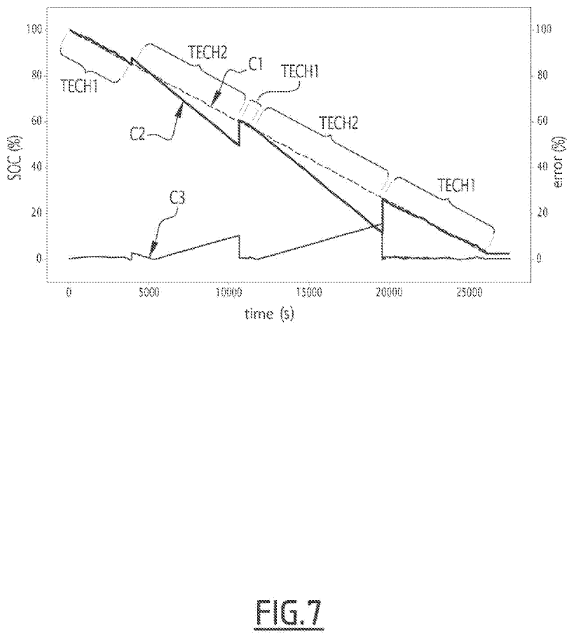

FIG. 7 is an experimental figure showing the interest of such recalibration for the case where the bias on the current is −2A.

In FIG. 7, the first curve C1 corresponds to the value of the real state of charge of the state of charge (SOC), the second curve C2 corresponds to the final estimated value of the state of charge, the third curve C3 corresponds to the estimation error.

When the final estimated value comes from the first technique, a brace delimiting the portion associated with the indication TECH1 is present in FIG. 7 and vice versa, when the final estimated value comes from the second technique, a brace delimiting the portion associated with the mention TECH2 is present in FIG. 7.

The portions for which the final estimated value comes from the first technique are the same as before (first zone Z1, fourth zone Z4 and junction between second zone Z2 and third zone Z3).

The portions for which the final estimated value comes from the second technique correspond to the remainder of the second Z2 and to the remainder of the third Z3 respectively.

In said portions, the final estimated value gradually moves away from the actual value of the state of charge (SOC) until same reaches a deviation such that the value obtained by the first technique becomes more reliable. It is then possible to correct the deviation ΔSOC which is shown in FIG. 7. The above corresponds to the recalibration and allows the error to be limited.

When, at the preceding iteration, the value according to the first technique SOC_{TECH1} was not reliable, the calculator 22 determines, during the determination step E56, the measurement bias on the current.

The measurement bias on the current is deduced by using the difference in the state of charge between the two techniques since the last instant at which the first computed state of charge value was determined to be unreliable.

Thereby, the measurement bias on current can be computed by the following formula:

$${I}_{biais} = C * \frac{{SOC}_{T 2} ( t ) - {SOC}_{T 1} ( t )}{Δ t}$$

In the preceding formula, I_{biais} refers to the measurement bias and Δt the time elapsed since the beginning of the time interval during which the second SOC_{TECH2} technique is used.

The measurement bias value thereby determined is stored by the calculator 22 to be used during the implementation of the correction step of the next iteration, as illustrated in FIG. 3 by the arrow 58.

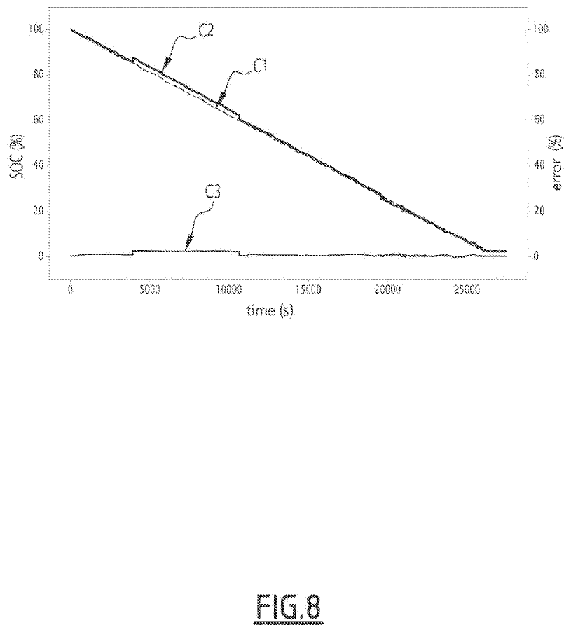

The interest of correcting the bias [on the] current appears well with FIG. 8 which corresponds to the same experimental conditions as the conditions of FIG. 7 except that the measurement bias is corrected.

The reduction in the error obtained is obvious.

The output of the estimated value of the state of charge (SOC) is illustrated schematically by the element 60 shown in FIG. 1. The estimated value is e.g. displayed on a display device.

In each case, the estimated value is thus the most reliable value.

Such a method can thus be used for estimating with better accuracy the value of the state of charge (SOC) of the electrochemical element 12.

Indeed, the method corresponds to the use of a hybrid model using two distinct techniques: a first technique coming from the world of machine learning based on the application of a self-corrected neural network and a second technique from the world of measurement and based on coulometric counting.

Such hybrid model is apt to select the best of the two values.

Indeed, it should be noted that such gain in accuracy is obtained with a relatively low computational cost compared to the use of the second technique alone because the neural network used has a very limited memory footprint (few neurons). Such results in the gain in accuracy stays compatible with an embedded application.

Moreover, the method can be also used for performing a recalibration of the second technique while the electrochemical element 12 is in usual operation, even in the flat portion Z23. As a result, the electrochemical element 12 thereby can continue the mission thereof while having a good estimation of the state of charge (SOC). A better availability of the electrochemical element 12 and/or avoiding oversizing of the battery 10 result therefrom.

Finally, due in particular to the choice of a neural network that estimates only on the basis of current values without any memory effect, the first technique is relatively robust to the bias on the current. As a result, the deviation caused by a bias on the current can be compensated for, resulting in increased accuracy.

It should also be noted that the statistical error profile is repeatable regardless of the types of use, which was unexpected. The statistical error profile is certainly related to the chemistry of the electrochemical element 12 but invariant according to the use, which makes the process more suitable for being used in a wide variety of possible applications.

Other embodiments having the aforementioned advantages are also conceivable.

More particularly, it is possible to calculate the value of the state of charge (SOC) of the electrochemical element 12 according to only one technique for reducing the computational load.

In such a case, the most reliable technique among the first technique and the second technique is determined on the basis of a criterion of reliability dependent on the value of the correction function for the computed value of the state of charge (SOC) and only when the technique determined as being reliable is not the technique that was the subject of the computation, is the latter computed.

As a result, computing two values at each instant is prevented, knowing that one of the two will not be used.

It is even possible to envisage a switchover system, i.e. that the technique according to which the value of the state of charge (SOC) of the electrochemical element 12 is computed at the instant t is the technique which has been determined as being reliable at the preceding instant.

As a result, the number of times a value of state of charge (SOC) is computed after the determination step E46 is reduced, because the determined technique is different from the technique chosen to perform the computation during the computation step E44.

1. A method for estimating the state of charge of at least one electrochemical element of a battery,
the method being implemented by a calculator, the calculator storing a first model giving from a value of voltage, a value of current, a value of temperature and a value of capacitance of the at least one electrochemical element the value of the state of charge of the at least one electrochemical element, the first model being a trained neural network, the calculator storing a correction function giving, for each value of the state of charge, the statistical error of estimation by the first model,
the method comprising, for a plurality of instants, the steps of:
obtaining values of the voltage, the current, the temperature and the capacitance of at least one electrochemical element,
computation of the value of the state of charge of at least one electrochemical element according to at least one technique, the technique being a first technique or a second technique,
the first technique including the following operations:
application of the first model on the value of the voltage, the current, the temperature and the capacitance of the at least one electrochemical element at the same instant, to obtain an estimated value of the state of charge, and
application of the correction function to the estimated value of the state of charge, to obtain a first computed value of the state of charge,
the second technique including the following operations:
computation of the value of the amount of charge accumulated by using the obtained values of current,
deduction of a second computed value of the state of charge by computing the ratio of the value of the accumulated charge quantity and the capacitance of the at least one electrochemical element,
determination of the most reliable technique among the first technique and the second technique according to a reliability criterion depending on the value of the statistical error of estimation of the model corresponding to the first model corrected by the correction function for the first computed value of the state of charge,
computation of the computed value of the state of charge according to the technique determined as being reliable if the value has not been computed previously, and
selection of the computed value of the state of charge according to the technique determined as the estimated value of the state of charge.

2. The method for estimating according to claim 1, wherein the method further includes a step of correcting the computed accumulated charge quantity used by the second technique so that the computation of the second technique leads to obtaining the first computed value of state of charge when the first technique is determined as being reliable.

3. The method for estimating according to claim 1, wherein the method further includes a step of correcting the value of current obtained by subtracting the measurement bias on the current, in order to obtain a corrected value of the current, the steps of computation being applied to the corrected value of the current.

4. The method for estimating according to claim 3, wherein the method further includes, when the first technique is determined as being reliable at an instant after a time interval during which the second technique has been determined as being reliable at each instant in the time interval, a step of determining the measurement bias on the current by using the difference of state of charge between the two techniques since the beginning of the time interval.

5. The method for estimating according to claim 1, wherein the neural network of the first model is a multilayer perceptron.

6. The method for estimating according to claim 1, wherein the neural network of the first model includes a number of neurons less than or equal to 100.

7. The method for estimating according to claim 1, wherein the at least one electrochemical element having a state of charge open circuit voltage characteristic with a flat portion, a flat portion being a portion wherein the variation of the open circuit voltage is less than 30 mV for a variation of at least 10% of the state of charge.

8. The method for estimating according to claim 1, wherein the at least one electrochemical element comprises an active cathode material chosen from the following groups or mixtures thereof:
i) a compound with the formula LiₓFe_{1-y}M_{y}PO₄(LFMP) where M is selected from the group consisting of B, Mg, Al, Si, Ca, Ti, V, Cr, Mn, Co, Ni, Cu, Zn, Y, Zr, Nb, and Mo; and 0.8≤x≤1.2; 0≤y≤0.6,
ii) a compound with the formula LiₓMn_{1-y-z}M′_{y}M″_{z}PO₄ (LMP), where M′ and M″ are different from each other and are selected from the group consisting of B, Mg, Al, Si, Ca, Ti, V, Cr, Fe, Co, Ni, Cu, Zn, Y, Zr, Nb, and Mo, with 0.8≤x≤1.2; 0≤y≤0.6; 0≤z≤0.2;
iii) a compound with the formula LiₓMn_{2-y-z}Ni_{y}M_{z}O_{4-d-c}F_{c} (LMNO), where M represents one or a plurality of elements chosen from the group consisting of B, Mg, Al, Si, Ca, Ti, V, Cr, Fe, Co, Ni, Cu, Zn, Y, Zr, Nb, and Mo; and 1≤x≤1.4; 0≤y≤0.6; 0≤z≤0≤d≤1; 0≤c≤1,
iv) a compound with the formula LiₓMn_{2-y-z}M′_{y}M″_{z}O₄ (LMO), where M′ and M″ are chosen from the group consisting of B, Mg, Al, Si, Ca, Ti, V, Cr, Fe, Co, Ni, Cu, Zn, Y, Zr, Nb, and Mo; M′ and M″ being different from each other, and 1≤x≤1.4; 0≤y≤0.6; 0≤z≤0.2; and
v) a compound with the formula LiVPO₄F (LVPF).

9. A calculator adapted to estimate the state of charge of at least one electrochemical element of a battery,
the calculator storing a first model giving from a value of voltage, a value of current, a value of temperature and a value of capacitance of the at least one electrochemical element the value of the state of charge of the at least one electrochemical element, the first model being a trained neural network, the calculator storing a correction function giving, for each value of the state of charge, the statistical error of estimation by the first model,
the calculator being, for a plurality of instants, adapted to:
obtain values of the voltage, the current, the temperature and the capacitance of at least one electrochemical element,
compute the value of the state of charge of at least one electrochemical element according to at least one technique, the technique being a first technique or a second technique,
the first technique including the following operations:
application of the first model on the value of the voltage, the current, the temperature and the capacitance of the at least one electrochemical element at the same instant, to obtain an estimated value of the state of charge, and
application of the correction function to the estimated value of the state of charge, to obtain a first computed value of the state of charge,
the second technique including the following operations:
computation of the value of the amount of charge accumulated by using the obtained values of current,
deduction of a second computed value of the state of charge by computing the ratio of the value of the accumulated charge quantity and the capacitance of the at least one electrochemical element,
determine the most reliable technique among the first technique and the second technique according to a reliability criterion depending on the value of the statistical error of estimation of the model corresponding to the first model corrected by the correction function for the first computed value of the state of charge
compute the computed value of the state of charge according to the technique determined to be reliable if the value has not been computed previously, and
select the computed value of the state of charge according to the technique determined as the estimated value of the state of charge.

10. The calculator according to claim 9, wherein the calculator is also adapted to correct the computed accumulated charge quantity used by the second technique so that the computation of the second technique results in obtaining the first computed state of charge value when the first technique is determined as being reliable.

11. A system for managing at least one electrochemical element of a battery, the at least one electrochemical element having terminals, the system for managing comprising:
a voltage sensor adapted to measure the voltage at the terminals of at least one electrochemical element,
a current voltage sensor adapted to measure the current at the terminals of said at least one electrochemical element,
a temperature sensor adapted to measure the temperature of said at least one electrochemical element, and
a calculator according to claim 9.

12. A battery comprising:
at least one electrochemical element, and
a system for managing according to claim 11.
